(19) United States
(12) Patent Application Publication
(10) Pub. No.: US 2007/0133170 A1
(43) Pub. Date: Jun. 14, 2007

(54) Self-protection device of water-cooled dissipation system for computer

(75) Inventor: Tzu-Yi Yang, Taipei (TW)

Correspondence Address: BACON & THOMAS, PLLC, 625 SLATERS LANE, FOURTH FLOOR, ALEXANDRIA, VA, 22314, US

(73) Assignee: Inventec Corporation, Taipei (TW)

(21) Appl. No.: 11/296,229

(22) Filed: Dec. 8, 2005

(51) Int. Cl. H05K 7/20

(52) U.S. Cl. 361/699; 165/61; 165/104.14

(57) ABSTRACT

A self-protection device of water-cooled heat dissipation system, applicable to a computer, includes a circulation route for a suitable amount of coolant flowing therein along a water tank, a pump and a heat exchanger; and a control module, electrically connected between the water-cooled heat dissipation system and a power supply of the computer system, for detecting whether if the water-cooled heat dissipation system is at a normal state. The control signal of the control module is to allow the computer turning on when the water-cooled heat dissipation system is checked normal. Otherwise, the power supply of the computer is stopped and an alarm is generated when the water-cooled heat dissipation system is abnormal.

### BACKGROUND OF THE INVENTION

1. Field of Invention

The invention generally relates to a self-protection device of water-cooled heat dissipation system, and in particular relates to a water-cooled heat dissipation system applicable to a computer for cooling heat-generating elements and checking itself before the computer being started.

2. Related Art

In a computer system, a central processing unit (CPU) or other chips generate heat caused by high frequency oscillation (HFO) during operating. The chip generates heat that will cause instability of operation. Therefore, in a computer, a cooler having a fan and a heatsink (with radiation fins) attached to the CPU is generally used.

However, as operation speed of newly-made CPU being increased, the performance of fan cooler becomes insufficient.

To solve the problem of insufficient heat dissipating efficiency, there have been water cooling systems for computer being developed, such as that being disclosed in Taiwan Utility Patent No. M252257 and Laid-open Patent Nos. 585307 and 578999.

A water-cooled heat dissipation system uses water as coolant. The water has to be supplemented after a period of working time, so the user has to check the water frequently. In order to indicate a user the remainder of coolant, a water-cooling system in Taiwan Laid-open Patent No. 595762 is equipped with a checking window and light source on a water reservoir. However, the system has the following inconvenience:

1) The coolant remainder being checked only by user, instead of automatically inspected by the system, is inconvenient for users; and

2) The checking window only shows the water level. However, other failures such as pipe leakage or pump failure cannot be indicated.

### SUMMARY OF THE INVENTION

The object of the invention is to solve the aforesaid problems and to provide a water-cooled heat dissipation system that can check the conditions itself.

Another object of the invention is to provide a self-protection device of water-cooled heat dissipation system for a computer that checks itself before the computer starts.

In order to achieve the objects, a self-protection device of water-cooled heat dissipation system, applicable to a computer, includes a circulation route for a suitable amount of coolant flowing therein along a water tank, a pump and a heat exchanger; and a control module, electrically connected between the heat dissipation system and a power source of the computer system, for detecting whether if the water-cooled heat dissipation system is at a normal state, and outputting a corresponding control signal to the power source.

The control signal of the control module is to allow the computer turning on when the water-cooled heat dissipation system is checked normal. On the contrary, the power source of the computer is stopped when the water-cooled heat dissipation system is checked abnormal.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a systematic diagram of a self-protection device of water-cooled heat dissipation system of the invention;

FIG. 2 is an operational flowchart of a self-protection device of water-cooled heat dissipation system of the invention; and

FIG. 3 is a functional diagram of a control module in a self-protection device of water-cooled heat dissipation system of the invention.

### DETAILED DESCRIPTION OF THE INVENTION

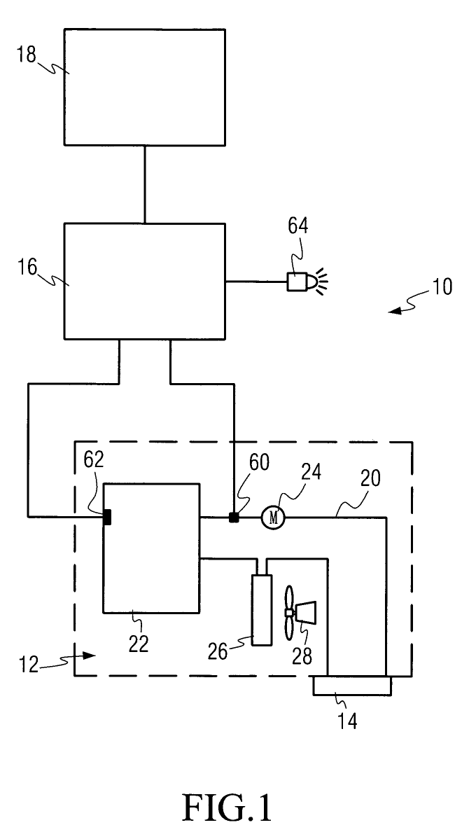

As shown in FIG. 1, a self-protection device 10 of water-cooled heat dissipation system 12 according to the invention is applicable to an unshown computer system, such as a desktop computer or a server.

The water-cooled heat dissipation system 12 includes a circulation route 20 connecting among a tank 22, a pump 24 and a heat exchanger 26. The circulation route 20 passes through the vicinity of a CPU 14 of the computer system.

The circulation route 20 mainly includes several pipes or ducts (which are of prior arts and will not be described herein) for circulating a suitable amount of coolant (such as water) flowing therein. The tank 22 stores a suitable amount of coolant to supplement the circulation. The pump 24 pressures the coolant to circulate in the circulation route 20. The heat exchanger 26 can be a cooler or heatsink with radiation fins. A fan 28 expels air to cool down the coolant flowing through the heat exchanger 26.

The self-protection device 10 further comprises a control module 16 for detecting if the circulation route 20 is in a normal condition.

The control module 16 is connected between a power supply 18 and the water-cooled heat dissipation system 12. In the embodiment, the control module 16 includes a flow detector 60 installed in the circulation route 20, a water level detector 62 mounted on the tank 22 at a suitable position, and a control circuit (not shown in the drawing) for receiving signals of the flow detector 60 and the water level detector 62, comparing them with preset data and outputting suitable signals to an alarm 64 and/or the power supply 18.

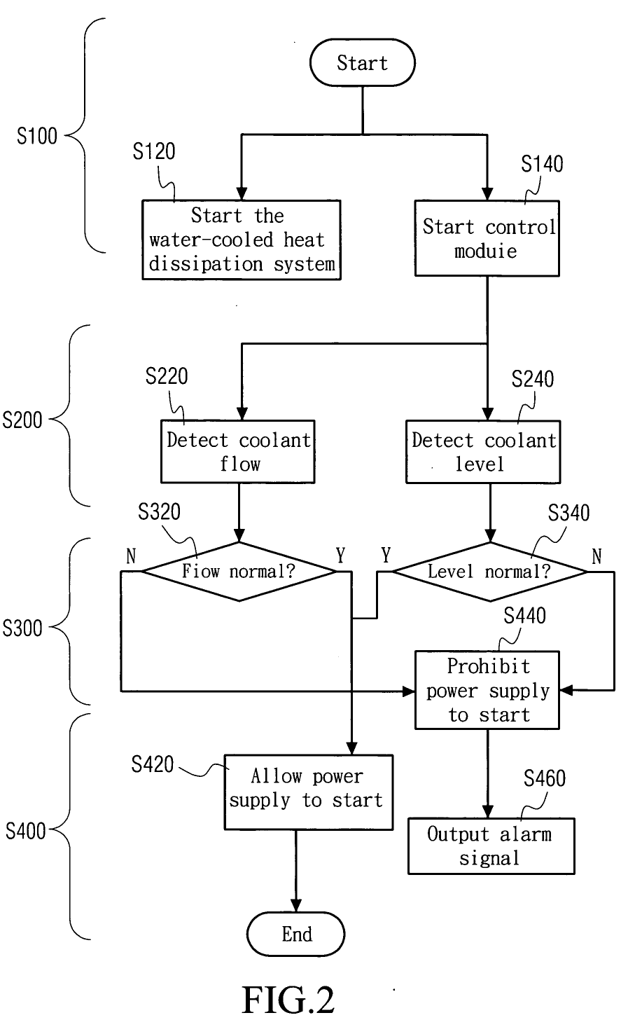

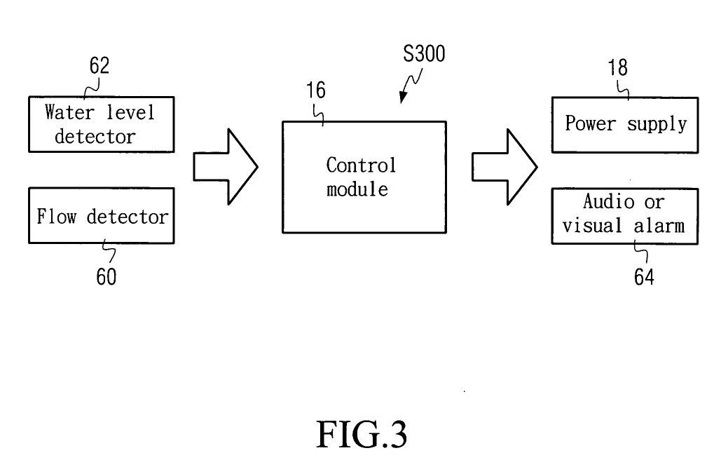

The operation of the self-protection device 10 will be further described with reference to FIG. 2 and FIG. 3. The steps are:
1) Starting steps (S 100) include starting the water-cooled heat dissipation system 12 (S 120) and starting the control module 16 (S140);
2) Detecting steps (S200) include detecting the state of the water-cooled heat dissipation system 12; include a step of detecting the coolant flow (S220) by measuring the flowing rate or flowing volume of coolant in a time period; and a step of detecting the coolant level in the tank 22 (S240) by the water level detector 62;
3) Judging steps (S300) include judging if there is no leakage in the circulation route 20 or the pump 24 is in a normal running condition (S320) by the control module 16 that calculates the coolant flow in the circulation route 20 and compares it with a build-in value; and judging if the coolant reservoir in the tank 22 is in a safety range (S340) by the control module 16 that detects the coolant level and compares it with a build-in value; and
4) Control steps (S400) include outputting a normal control signal (S420) to allow the power supply starting the computer when the control module 16 judges that the components in the water-cooled heat dissipation system 12 are normal and the coolant reservoir is sufficient; and outputting an abnormal signal (S440) to prohibit the power supply 18 starting the computer when the control module 16 judges that the water-cooled heat dissipation system 12 is abnormal. Meanwhile, outputting an alarm signal (S460) to an alarm 64 that provide alarm information.

By the aforesaid steps, the self-protection device 10 prevents the computer from starting and being damaged by heat dissipation failure when the water-cooled heat dissipation system is abnormal.

In practice, the control module 16 not only functions as above to detect the coolant flow and the tank reservoir, but also to detect the coolant temperature or the fan revolution. For example, a temperature detector is used to detect the temperature of the coolant; or a tachometer or similar detector is used to detect if the fan 28 works normally. The detector modifications are regarded as equivalents of the invention.

The alarm 64 can be a speech integrated circuit (IC) or a liquid crystal display (LCD) to provide audio or visual signals. Practically, when applying a display, such as LCD, other information such as the coolant flow or the reservoir information of the circulation route 20 is also displayed.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A self-protection device of water-cooled heat dissipation system, applicable to a computer, for cooling heat-generating elements, comprising:
a circulation route, having a suitable coolant flowing therein, and connecting at least a tank, a pump and a heat exchanger; and
a control module, electrically connecting to the circulation route and a power supply of the computer for detecting if the water-cooled heat dissipation system is normal and outputting a correspondent signal to the power supply.

2. The self-protection device of water-cooled heat dissipation system according to claim 1 wherein the computer is one chosen from server and desktop computers.

3. The self-protection device of water-cooled heat dissipation system according to claim 1 wherein the control module comprises a flow detector for detecting coolant flowing rate and/or flowing volume in the circulation route.

4. The self-protection device of water-cooled heat dissipation system according to claim 1 wherein the control module comprises a level detector for detecting the reservoir of the coolant on the tank.

5. The self-protection device of water-cooled heat dissipation system according to claim 1 wherein the control module comprises a temperature detector for detecting temperature of the coolant.

6. The self-protection device of water-cooled heat dissipation system according to claim 1 wherein the water-cooled heat dissipation system further comprises a fan; the control module comprises a tachometer for detecting revolution speed of the fan.

7. The self-protection device of water-cooled heat dissipation system according to claim 1 wherein the control module comprises a liquid crystal display (LCD) to show information of the water-cooled heat dissipation system and warnings.
